(19) United States
(12) Patent Application Publication
(10) Pub. No.: US 2025/0391701 A1
(43) Pub. Date: Dec. 25, 2025

(54) SUBSTRATE TREATMENT APPARATUS AND SUBSTRATE TREATING METHOD

(71) Applicant: SAMSUNG ELECTRONICS CO., LTD., Suwon-si (KR)

(72) Inventors: Woo-Yong JUNG, Suwon-si (KR); Moonjong KANG, Suwon-si (KR); Young-Min SEO, Suwon-si (KR); Seungyoon LEE, Suwon-si (KR); Chan HWANG, Suwon-si (KR)

(21) Appl. No.: 18/982,620

(22) Filed: Dec. 16, 2024

(30) Foreign Application Priority Data
Jun. 19, 2024 (KR) 10-2024-0079599

(51) Int. Cl. H01L 21/683; H01L 21/66; H01L 21/67

(52) U.S. Cl. CPC H01L 21/6838; H01L 21/67253; H01L 22/12

(57) ABSTRACT

A substrate treating method includes identifying correlation data between a height value of each of a plurality of reference substrates and a vacuum pressure applied to secure each of the plurality of reference substrates to a chuck, and determining, based on the correlation data and a height value of a substrate, a flow amount of a fluid discharged by a vacuum pump to produce a vacuum pressure applied to secure the substrate to the chuck.

### CROSS-REFERENCE TO RELATED APPLICATION(S)

This application claims the benefit of Korean Patent Application No. 10-2024-0079599, filed on Jun. 19, 2024, in the Korean Intellectual Property Office, the disclosure of which is incorporated herein by reference in its entirety.

### BACKGROUND

### 1. Field of the Invention

The present disclosure relates to a substrate treatment apparatus and a substrate treating method.

### 2. Description of the Related Art

With the advance of electronic apparatus, a change in height of a surface of a substrate used to manufacture an electronic apparatus, such as a wafer, a printed circuit board, or the like, may become complicated and irregular, and such a substrate may not be secured adequately in various processes such as transfer or exposure. Accordingly, a way of accurately controlling a position of the substrate and fixing the substrate for manufacturing the electronic apparatus may be required.

### SUMMARY OF THE INVENTION

An aspect provides a substrate treatment apparatus and a substrate treating method for fixing a substrate to a chuck.

However, the goals to be achieved by example embodiments of the present disclosure are not limited to the objectives described above and other objects may be inferred from the following example embodiments.

According to an aspect, there is provided a substrate treating method including identifying correlation data between a height value of each of a plurality of reference substrates and a vacuum pressure applied to secure each of the plurality of reference substrates to a chuck, and determining, based on the correlation data and a height value of a substrate a flow amount of a fluid discharged by a vacuum pump to produce a vacuum pressure applied to secure the substrate to the chuck.

According to another aspect, there is also provided a substrate treatment apparatus including a memory configured to store correlation data between a height value of each of a plurality of reference substrates and a vacuum pressure applied to secure each of the plurality of reference substrates to a chuck, and a processor configured to identify the correlation data and determine, based on the correlation data and a height value of a substrate, a flow amount of a fluid discharged by a vacuum pump to produce a vacuum pressure applied to secure the substrate to the chuck.

According to still another aspect, there is also provided a substrate treatment apparatus including a height sensor configured to measure a height value of a substrate, a vacuum pump, a chuck configured to support the substrate, a controller in communication with the height sensor and the vacuum pump, wherein the controller is configured to acquire an estimated vacuum pressure for the substrate corresponding to the height value of the substrate based on correlation data between height values of a plurality of reference substrates and vacuum pressures applied to secure the plurality of reference substrates to the chuck, and determine a flow amount of a fluid discharged by the vacuum pump, based on the estimated vacuum pressure, and an exposure part configured to expose the substrate to light when the substrate is secured to the chuck.

Additional aspects of example embodiments will be set forth in part in the following description and drawings.

According to proposed example embodiments, one or more of the following effects may be expected.

According to example embodiments, it is possible to provide a substrate treatment apparatus and a substrate treating method for fixing a substrate to a chuck.

According to example embodiments, it is possible to fix the substrate on which a height is changed depending on a position.

According to example embodiments, it is possible to minimize a failure rate in a process due to an unfixed substrate.

Effects of the present disclosure are not limited to those described above and other effects may be made apparent to those skilled in the art from the following description.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram for describing a method of manufacturing an electronic apparatus according to example embodiments;

FIG. 2 is a diagram for describing a substrate and a chuck according to example embodiments;

FIG. 3 is a diagram for describing a substrate treating method according to example embodiments;

FIG. 4 is a diagram for describing a substrate treating method according to example embodiments;

FIG. 5 is a diagram for specifically describing a substrate treating method according to example embodiments;

FIGS. 6A and 6B are diagrams for describing a substrate according to example embodiments;

FIG. 7 is a diagram for describing height values by position according to example embodiments;

FIG. 8 is a diagram for describing a scheme of determining a height value according to example embodiments;

FIG. 9 is a diagram for describing correlation data according to example embodiments;

FIG. 10 is a diagram for describing an estimated vacuum pressure and a weighted value according to example embodiments;

FIGS. 11A and 11B are block diagrams for describing a substrate treatment apparatus according to example embodiments;

FIG. 12 is a block diagram for describing a substrate treatment apparatus according to example embodiments;

FIG. 13 is a diagram for describing a substrate treatment apparatus according to example embodiments; and

FIG. 14 is a diagram for describing a state of warpage of a substrate according to example embodiments.

### DETAILED DESCRIPTION

Terms used in the example embodiments are selected, as much as possible, from general terms that are widely used at present while taking into consideration the functions obtained in accordance with the present disclosure, but these terms may be replaced by other terms based on intentions of those skilled in the art, customs, emergence of new technologies, or the like. Also, in a particular case, terms that are arbitrarily selected by the applicant of the present disclosure may be used. In this case, the meanings of these terms may be described in corresponding description parts of the disclosure. Accordingly, it should be noted that the terms used herein should be construed based on practical meanings thereof and the whole content of this specification, rather than being simply construed based on names of the terms.

In the entire specification, when an element is referred to as “including” another element, the element should not be understood as excluding other elements so long as there is no special conflicting description, and the element may include at least one other element. In addition, the terms “unit” and “module”, for example, may refer to a component that exerts at least one function or operation, and may be realized in hardware or software, or may be realized by combination of hardware and software.

In the following description, example embodiments of the present disclosure will be described in detail with reference to the drawings so that those skilled in the art can easily carry out the present disclosure. The present disclosure may be embodied in many different forms and is not limited to the embodiments described herein.

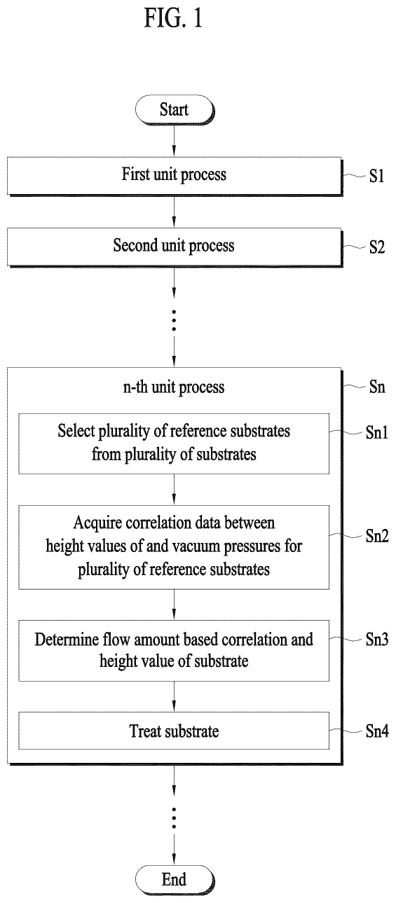

FIG. 1 is a diagram for describing a method of manufacturing an electronic apparatus according to example embodiments.

Referring to FIG. 1, the manufacturing method of the electronic apparatus according to example embodiments may include a plurality of unit processes S1, S2, Sn, and so on. As the unit processes S1, S2, Sn, and so on progress for each substrate, each electronic apparatus may be manufactured.

In example embodiments, the electronic apparatus may be in one of various forms such as a central processing unit, a graphics processing unit, an application processing unit, a neural processing unit, a digital signal processor, a dynamic random access memory (DRAM), a static random access memory (SRAM), a flash memory, a main board, an image sensor, various semiconductor sensors, micro-electro-mechanical systems (MEMS), a light emitting diode, a laser diode, an amplifier, a filter, a modulator, a photodiode, a solar power generation device, a communication circuit, an integrated circuit, a semiconductor device, and the like.

In example embodiments, a substrate may include at least one of a silicon (Si) wafer, a gallium arsenide (GaAs) wafer, a sapphire (Al₂O₃) wafer, a germanium (Ge) wafer, a gallium nitride (GaN) wafer, a silicon carbide (SiC) wafer, a glass substrate, a ceramic substrate, a printed circuit board. In example embodiments, the substrate may be a thin film of which a length in a height-wise direction is greatly smaller than a length in a horizontal direction. In example embodiments, the substrate may have various forms such as a shape circular or quadrangular in the height-wise direction.

Hereinafter, a content common to the unit processes S1, S2, Sn, and so on will be described with reference to an n-th unit process Sn. Here, n is a natural number.

The n-th unit process Sn may include operation Sn1 of selecting a plurality of reference substrates from a plurality of substrates, operation Sn2 of acquiring correlation data between height values of and vacuum pressures for the plurality of reference substrates, operation Sn3 of determining a flow amount based on the correlation data and a height value of the substrate, and operation Sn4 of treating the substrate. In example embodiments, a description of the n-th unit process Sn may be identically applied to other unit processes. In other example embodiments, unlike the n-th unit process Sn, at least one of the other unit processes may be modified and implemented to include an operation of fixing the substrate and an operation of treating the substrate.

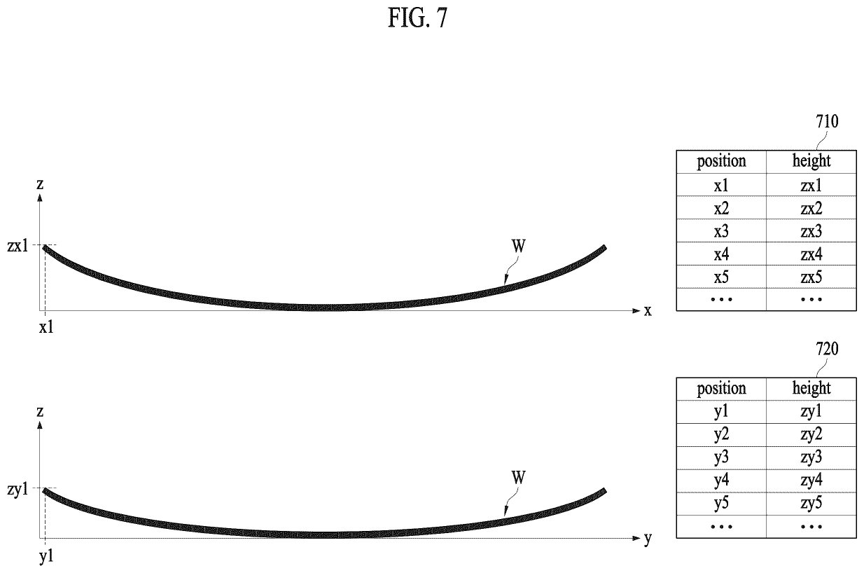

The term “height value”, as used herein, refers to a distance from a specific portion of the upper surface of a substrate to a surface upon which the substrate is placed, such as a chuck upon which the substrate is to be supported for processing. The height value of a substrate may vary along the upper surface thereof due to warpage of the substrate, etc. For example, as illustrated in FIG. 7, the upper surface at the outer peripheral edge portion of the substrate W has a height value (i.e., a distance along the z-axis from the upper surface of the substrate W to the x-axis) that is greater than a height value of the upper surface at radially inward locations.

A substrate treating method of the present disclosure may include at least a portion of the n-th unit process Sn. In example embodiments, the substrate treating method may include at least one of operation Sn1 of selecting the plurality of reference substrates from the plurality of substrates, operation Sn2 of acquiring the correlation data between the height values of and the vacuum pressures for the plurality of reference substrates, operation Sn3 of determining the flow amount based on the correlation data and the height value of the substrate, and operation Sn4 of treating the substrate. The substrate treating method may be performed by a substrate treatment apparatus.

In example embodiments, the substrate treatment apparatus may select the plurality of reference substrates from the plurality of substrates in operation Sn1. In other words, a portion of the plurality of substrates may be selected as a reference substrate. The plurality of substrates may be substrates for which an n−1-th unit process is completed (or progress thereof is completed) or substrates for which the n-th unit process is to be performed (or to progress). The reference substrate may be selected randomly from the plurality of substrates or selected in order of a process therefor being completed. The number of the reference substrates may be predetermined to be ten, fifteen, eighteen, twenty, or the like.

In example embodiments, the substrate treatment apparatus may acquire the correlation data between the height values of and the vacuum pressures for the plurality of reference substrates in operation Sn2. For example, a height value of each reference substrate may be measured, a vacuum pressure for each reference substrate may be measured in a state in which each reference substrate is loaded onto a chuck, and correlation data between the measured height value and the measured vacuum pressure (i.e., the vacuum pressure utilized to secure the substrate to the chuck) may be acquired. In example embodiments, the correlation data may show a correlation between the height value and the vacuum pressure. The correlation data may include a function for outputting an estimated value (or predicted value) according to an input value.

In example embodiments, the substrate treatment apparatus may determine the flow amount based on the correlation data and the height value of the substrate in operation Sn3. The term “flow amount”, as used herein, refers to the amount of fluid, such as air, per unit time that a vacuum pump discharges to produce a particular amount of vacuum. The vacuum is used to draw and secure the substrate to a chuck. The terms “vacuum” and “vacuum suction”, as used herein, are interchangeable. Here, the height value of the substrate may be an input value for the correlation data, and the flow amount may be a final output value. For example, when the height value of the substrate is input to the correlation data, the flow amount may be determined according to an output value that is output from the correlation data. Here, the output value that is output from the correlation data may be an estimated vacuum pressure. According to an embodiment of the present disclosure, by securely fixing a warped or otherwise non-flat substrate flat on the chuck, vacuum errors are reduced and process stability is improved. For example, the vacuum pressure may be a pressure applied to secure the substrate to the chuck. The estimated vacuum pressure may be a vacuum pressure that is acquired through the height value and the correlation data and may be a vacuum pressure that is estimated (or predicted), not a measured vacuum pressure. Also, the flow amount for vacuum suction of the substrate (i.e., for the vacuum suction utilized to secure the substrate to the chuck) may be determined by using the estimated vacuum pressure, and the substrate may be adhered to the chuck via vacuum suction according to the flow amount. In other words, unlike a feedback method of measuring a vacuum pressure and using the measured vacuum pressure as an input, the substrate treating method and the substrate treatment apparatus according to example embodiments of the present disclosure may adhere the substrate to the chuck via vacuum suction according to a feedforward method of adjusting the flow amount according to the estimated vacuum pressure.

In example embodiments, the substrate treatment apparatus may treat the substrate in operation Sn4. Performing of bonding treatment, heat treatment, oxidation treatment, exposure treatment, etching treatment, deposition treatment, cutting treatment, packaging treatment, and transfer treatment for the substrate may be included. The bonding treatment may be stacking of multiple substrates in a height-wise direction and bonding of the multiple substrates as one substrate. The heat treatment may be heating of the substrate at a high temperature. The oxidation treatment may be forming of an oxide film on a surface of the substrate. The exposure treatment may be exposing of some areas of a photoresist to light such as ultraviolet or extreme ultraviolet through a mask after applying the photoresist to the surface of the substrate. The etching treatment may be removing of some areas of the surface of the substrate. The deposition treatment may be covering of the surface of the substrate with a thin film of a material. The cutting treatment may be cutting of the substrate into a plurality of segments. The packing treatment may be electrically connecting of the substrate or the cut substrate with another substrate. The transfer treatment may be transferring of the substrate to an equipment for performing a next unit process. Treatment of the substrate may be construed up to an extent to which the treatment is modified and implemented to be one of various manufacturing processes for the substrate in addition to the methods described above.

Hereinafter, example embodiments of the present disclosure including the substrate treating method will be specifically described.

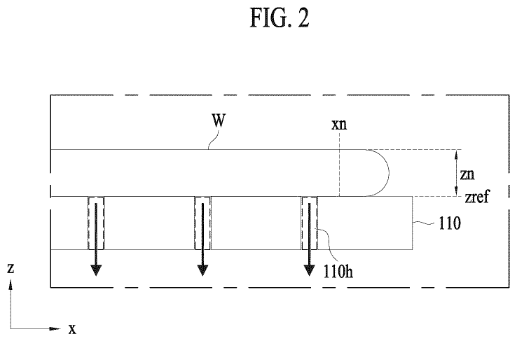

FIG. 2 is a diagram for describing a substrate and a chuck according to example embodiments. FIG. 2 illustrates a state in which the chuck is loaded with the substrate.

Referring to FIG. 2, a chuck 110 according to example embodiments may be a device for fixing a substrate W (or a reference substrate). For example, while the substrate W is treated according to various treating methods such as etching treatment, deposition treatment, or exposure treatment, the chuck 110 may fix the substrate W so that the substrate W is not moved.

In example embodiments, at least one hole 110h may be formed to the chuck 110. For example, the hole 110h may be formed by an area of the chuck being penetrated in a height-wise direction (e.g., a z-axis direction).

In example embodiments, the substrate W may be loaded (or disposed) above the chuck 110. The chuck 110 may adsorb the substrate W through a vacuum pressure. For example, a fluid (e.g., a gas or the like) existing in the hole 110h or between an upper surface of the chuck 110 and a lower surface of the substrate W may be sucked or drawn through a vacuum pump in a state in which the substrate W is loaded above the chuck 110. When the fluid is drawn by the vacuum pump, vacuum pressure is formed below the substrate W. The vacuum pressure may be indicated with a value or a digital value in various units such as Pascal (Pa), Kilopascal (KPa), Torr, bar, or atmosphere (atm).

In example embodiments, the vacuum pressure may be generated according to a flow amount (i.e., the amount of fluid, such as air, drawn by the vacuum pump to produce vacuum). For example, when the flow amount is increased, a lower vacuum pressure may be generated (e.g., the flow amount is proportional to the vacuum pressure generated by the vacuum pump). The flow amount may show an amount (e.g., a volume or a mass) per unit time of the fluid which flows for suction of (or fixing) the substrate W. The flow amount may be indicated with a value or a digital value in various units such as liter per second (L/sec), liter per minute (L/min), liter per hour (L/h), gallon per sec (gal/sec), gallon per min (gal/min), or gallon per hour (gal/h).

The vacuum pressure may be a pressure lower than an upper pressure applied to an upper portion of the substrate W (e.g., an atmospheric pressure). That is, as a pressure higher than the vacuum pressure which is applied to a lower part of the substrate W is applied to the upper portion of the substrate W, the substrate W may be fixed to the chuck which is positioned downward.

With heat treatment or a product being advanced, depending on positions, a height value of the substrate W may be different, or the substrate W may be partially bent. The height value may show a length in the height-wise direction (e.g., the z-axis direction) from a reference height zref. The reference height zref may be an upper end of the chuck 110, but the reference height zref may be modified and implemented to be at various set positions. For example, in a first horizontal direction (e.g., an x-axis direction), the substrate W may have an n-th height value zn at an n-th position xn and another height value different from the n-th height value zn at another position different from the n-th position xn. In this case, when an external space and the hole 110h of the chuck 110 is connected through a gap occurring between the lower surface of the substrate W and the upper surface of the chuck 110, a vacuum may not be properly formed in the hole 110h. Accordingly, the vacuum pressure may be increased. In addition, a difference between the upper pressure to the substrate W and the vacuum pressure may be decreased, or the upper pressure to the substrate W and the vacuum pressure may be equalized. Accordingly, the substrate W may not be fixed to the chuck 110 and may be easily separated from a correct position.

A substrate treating method and a substrate treatment apparatus according to example embodiments of the present disclosure may determine the flow amount based on the height value of the substrate W and correlation data that is acquired through the reference substrate. In other words, the substrate treating method and the substrate treatment apparatus may determine an optimal flow amount for stably fixing the substrate W.

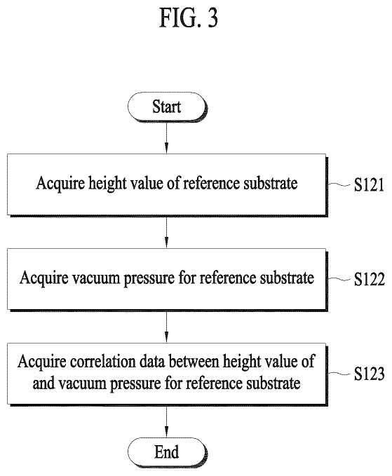

FIG. 3 is a diagram for describing a substrate treating method according to example embodiments.

Referring to FIG. 3, the substrate treating method according to example embodiments of the present disclosure may include operation S121 of acquiring a height value of a reference substrate, operation S122 of acquiring a vacuum pressure for the reference substrate, and operation S123 of acquiring correlation data between the height value of and the vacuum pressure for the reference substrate. When a plurality of reference substrates are present, the substrate treating method may include an operation of acquiring a height value of each of the plurality of reference substrates, an operation of acquiring a vacuum pressure for each of the plurality of reference substrates, and operation of acquiring correlation data between the height value of and the vacuum pressure for each of the plurality of reference substrates. In example embodiments, the reference substrate may be a substrate selected from a plurality of substrates W for which an identical unit process is to be performed.

In example embodiments, a substrate treatment apparatus may acquire the height value of the reference substrate in operation S121. For example, the height value of the reference substrate may be acquired by measuring at least one height value of the reference substrate. A description of acquiring the height value of the reference substrate may be identically applied to acquiring a height value of the substrate W.

In an example embodiment, the height value may be acquired through a height sensor. For example, the height sensor may be a triangulation-type height sensor or a time-of-flight (ToF)-type height sensor. In this case, the height sensor may include an oscillator and a receiver. However, it is merely an example, the height sensor may be modified and implemented to be a height sensor for measuring the height value with various schemes such as a structured light scheme of measuring a height value by projecting patterned light and analyzing a modified pattern or a scheme of measuring a height value through contact with a probe.

For example, in a case of a triangulation scheme, in a state in which the oscillator and the receiver are disposed above the reference substrate, the oscillator and the receiver may project an electromagnetic wave (e.g., a laser, infrared, or the like) on a surface of the reference substrate, and the receiver may receive the electromagnetic wave which is reflected on and returned from the surface of the reference substrate and may measure an angle of reception of the electromagnetic wave. The height value of the reference substrate may be acquired according to the angle of reception of the electromagnetic wave. Here, when a line that links the oscillator, the receiver, and a reflection point is drawn, a triangle may be formed. In this case, the height value may be calculated with an equation “d2=d1×tan(θ)”. For example, θ may be the angle of reception of the electromagnetic wave, d1 may be a premeasured value and a distance between the oscillator and the receiver. d2 may be a distance between the oscillator and the reflection point. A value obtained by subtracting the d2 from a premeasured height value of the oscillator may be acquired as the height value of the reference substrate. The above-described equation is merely an example embodiment and may be modified and implemented to be various equations.

For example, in a case of a ToF scheme, in a state in which the oscillator and the receiver are disposed above the reference substrate, the oscillator may project an electromagnetic wave (e.g., a laser, an ultrasonic wave, or the like) on the surface of the reference substrate, and the receiver may receive the electromagnetic wave which is reflected on and returned from the surface of the reference substrate and may measure a distance between the oscillator and a reflection point by using a time difference between a time point of projection and a time point of reception of the electromagnetic wave and a speed of the electromagnetic wave. A value obtained by subtracting the distance between the oscillator and the reflection point from the premeasured height value of the oscillator may be acquired as the height value of the reference substrate.

In an example embodiment, the height value of the reference substrate may be a value of a difference between a largest height value among height values by position on the reference substrate in a first horizontal direction and a largest height value among height values by position on the reference substrate in a second horizontal direction. For example, a height value may show a length in a height-wise direction (e.g., a z-axis direction). The height value may be indicated with a value or a digital value in various units such as millimeter (mm), micrometer (μm), or the like. The first horizontal direction (e.g., an x-axis direction) may be a direction perpendicular to the height-wise direction (e.g., the z-axis direction). The second horizontal direction (e.g., a y-axis direction) may be a direction different from the first horizontal direction (e.g., the x-axis direction) and perpendicular to the height-wise direction (e.g., the z-axis direction).

In example embodiments, the substrate treatment apparatus may acquire the vacuum pressure for the reference substrate in operation S122. For example, the vacuum pressure may be measured and acquired in a state in which the vacuum pressure is applied to the chuck 110 (i.e., applied to openings in an upper surface of the chuck 110) which is loaded with the reference substrate. In example embodiments, the vacuum pressure for the reference substrate may be a vacuum pressure measured for the reference substrate. In example embodiments, the vacuum pressure may be generated according to a flow amount of a reference flow amount value.

The vacuum pressure according to example embodiments may be acquired through a pressure sensor. For example, the pressure sensor may be an ionization sensor that ionizes a gas molecule through collision with an electron and measures a vacuum pressure by sensing an electrical current generated by the ionized gas molecule or a thermocouple gauge that measures a vacuum pressure by sensing a degree of heat loss in a heated filament with a principle that heat transfer is lowered when the vacuum pressure is low (that is, in a state of a high vacuum). However, it is merely an example embodiment. The pressure sensor may be modified and implemented to be various pressure sensors such as a diaphragm sensor in which an electrical characteristic (e.g., resistance, capacitance, or the like) of a diaphragm is changed as a shape of the diaphragm is changed when a pressure is applied and that measures a vacuum pressure by sensing an electrical characteristic change or an optical fiber sensor in which a path of light in an optical fiber is changed as the optical fiber is changed when a pressure is applied and that measures a vacuum pressure by sensing a path change. In example embodiments, the vacuum pressure may be a value obtained by subtracting a measured pressure, which is measured by the pressure sensor, from a reference pressure (e.g., an atmospheric pressure or the like). In embodiments, the reference pressure may be referred to as a reference vacuum pressure. When the vacuum pressure is smaller than the reference pressure, the vacuum pressure may have a negative value.

In example embodiments, the substrate treatment apparatus may acquire the correlation data between the height value of and the vacuum pressure for the reference substrate in operation S123. For example, the height value and the vacuum pressure which are acquired for each of the plurality of reference substrates may be collected and stored, and the correlation data may be acquired based on the height value and the vacuum pressure by using a modeling scheme. The correlation data may include various functions such as a first-degree linear function, a logarithmic function, or an exponential function generated by using the modeling scheme. In example embodiments, the correlation data may be acquired based on the height value and the vacuum pressure through a variety of software such as Python, Excel, MATLAB, or Google Sheets. In example embodiments, a controller of the substrate treatment apparatus may acquire the correlation data and store the correlation data in a memory.

The height value of and the vacuum pressure may be stored as a data set. For example, the data set may be formed of a row and a column. In example embodiments, a height value and a vacuum pressure that are acquired through an identical reference substrate may be stored in an identical row, and the height value and the vacuum pressure may be individually stored in difference columns.

The modeling scheme may be a least squares method of finding a function for minimizing an error between a data set and the function. However, it is merely an example embodiment, and the modeling scheme may be modified and implemented to be various schemes such as random sample consensus (RANSAC) for finding a function having a smallest number of errors corresponding to an outlier among various functions generated by sampling a portion of a data set.

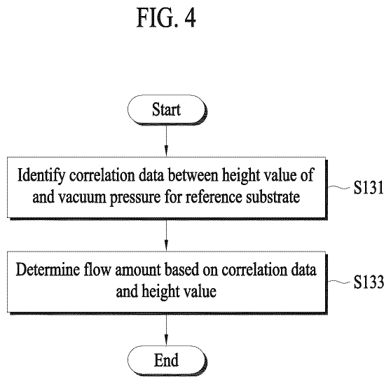

FIG. 4 is a diagram for describing a substrate treating method according to example embodiments.

Referring to FIG. 4, the substrate treating method according to example embodiments of the present disclosure may include operation S131 of identifying correlation data between a height value and a vacuum pressure for each of a plurality of reference substrates and operation S133 of determining a flow amount based on the correlation data and a height value of the substrate W. In example embodiments, a controller of a substrate treatment apparatus may identify the correlation data and determine the flow amount based on the correlation data and the height value of the substrate W.

In example embodiments, the substrate treatment apparatus may identify the correlation data between the height value of and the vacuum pressure for each of the plurality of reference substrates in operation S131. For example, the correlation data may be prepared or loaded to be in a usable state. For example, a memory may store in advance the correlation data between the height value and the vacuum pressure which are acquired for each of the plurality of reference substrates for which an identical unit process is to be performed. In order to treat the substrate W for which a unit process identical to that for a reference substrate is to be performed, the correlation data stored in the memory may be loaded.

In example embodiments, the substrate treatment apparatus may determine the flow amount based on the correlation data and the height value of the substrate W in operation S133. Operation S133 of determining the flow amount may include an operation of acquiring the height value of the substrate W. The above description for the reference substrate may be identically applied to a description of acquiring the height value of the substrate W.

In example embodiments, the substrate treatment apparatus may determine the flow amount based on the correlation data and the height value of the substrate W in operation S133. For example, a flow amount corresponding to an output value of the correlation data may be determined based on the correlation data and the height value of the substrate W. The output value of the correlation data may be an estimated vacuum pressure. The estimated vacuum pressure may be a vacuum pressure estimated when the vacuum pressure is generated according to a flow amount of a reference flow amount value in a state in which the substrate W is disposed (i.e., secured) to the chuck 110. The flow amount may be determined according to a value of the estimated vacuum pressure. In example embodiments, the flow amount may be a value obtained by applying a weighted value corresponding to the estimated vacuum pressure to the reference flow amount value. In other example embodiments, the flow amount may be the reference flow amount value or the value obtained by applying the weighted value corresponding to the estimated vacuum pressure to the reference flow amount value. The flow amount may show an amount of a flow per unit time of a fluid for suction of the substrate W. For example, the flow amount may be an amount of a flow per unit time of the fluid which is discharged by a vacuum pump to generate vacuum suction. The vacuum pump and the hole 110h of the chuck 110 may be connected through a pipe. The vacuum pressure may be formed in the hole 110h of the chuck 110 according to the flow amount, and the substrate W may be drawn under vacuum and fixed to the chuck 110 by the vacuum pressure.

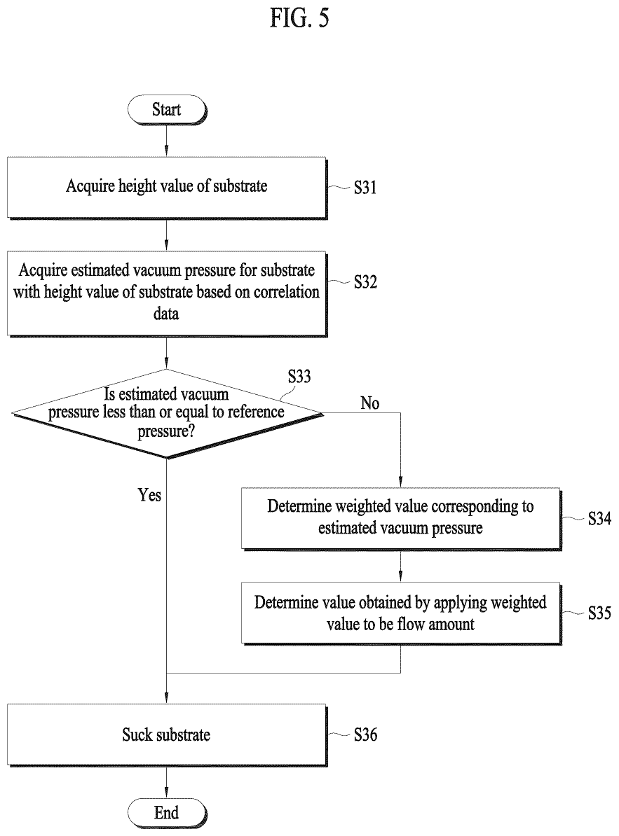

In example embodiments, operation S133 of determining the flow amount may include an operation of acquiring the estimated vacuum pressure for the substrate, which corresponds to the correlation data and the height value of the substrate W, and an operation of comparing the estimated vacuum pressure and a reference pressure. In an example embodiment, operation S133 of determining the flow amount may include determining the reference flow amount value to be the flow amount when the estimated vacuum pressure is less than or equal to the reference flow amount. In an example embodiment, operation S133 of determining the flow amount may include an operation of determining the value obtained by applying the weighted value corresponding to the estimated vacuum pressure to the reference flow amount value to be the flow amount when the estimated vacuum pressure is larger than the reference vacuum pressure. Details thereof will be described further specifically with reference to FIG. 5.

FIG. 5 is a diagram for specifically describing a substrate treating method according to example embodiments.

Referring to FIG. 5, the substrate treating method according to example embodiments of the present disclosure may include operation S31 of acquiring a height value of the substrate W, operation S32 of acquiring an estimated vacuum pressure for the substrate W based on correlation data and the height value of the substrate W, and operation S33 of comparing the estimated vacuum pressure and a reference pressure. The substrate treating method may further include operation S36 of determining a flow amount according to a result of comparison and applying vacuum suction to the chuck to adhere the substrate W to the chuck according to the determined flow amount.

In example embodiments, a substrate treatment apparatus may acquire the height value of the substrate W in operation S31. For example, the height value of the substrate W may be acquired by measuring at least one height value of the substrate W through a height sensor. In example embodiments, the height value of the substrate W may be a value of a difference between a largest height value among height values by position on the substrate W in a first direction (e.g., an X-axis direction) and a largest height value among height values by position on the substrate W in a second direction (e.g., a Y-axis direction). For example, the first direction may be different from the second direction (e.g., perpendicular, etc.). In example embodiments, the height value of the substrate W may be acquired in a manner identical to that for a height value of a reference substrate. As being redundant, a detailed description will be omitted.

In example embodiments, the substrate treatment apparatus may acquire the estimated vacuum pressure for the substrate W based on the correlation data and the height value of the substrate W in operation S32. For example, the estimated vacuum pressure for the substrate W, which corresponds to the height value of the substrate W, may be acquired through the correlation data. The estimated vacuum pressure may be a value acquired as an output value of the correlation data when the height value of the substrate W is applied as an input value of the correlation data. In example embodiments, a controller of the substrate treatment apparatus may acquire the estimated vacuum pressure for the substrate W based on the correlation data and the height value of the substrate W.

In example embodiments, the correlation data may include a linear function between a height value of each of a plurality of reference substrates and a vacuum pressure for each of the plurality of reference substrates. The linear function may be a first-degree function. For example, the linear function may be defined as an equation such as “Y=A×X+B”. A may be a gradient, B may be a constant, X may be an input variable (e.g., the height value), and Y may be an output variable (e.g., the vacuum pressure or the estimated vacuum pressure).

In example embodiments, the substrate treatment apparatus may compare the estimated vacuum pressure and the reference pressure in operation S33. A value of the estimated vacuum pressure and a value of the reference pressure may be compared with each other. Operation S33 of comparing the estimated vacuum pressure and the reference pressure may be modified and implemented to be omitted. In this case, operation S33 may progress by passing through operations S34 and S35.

In example embodiments, the substrate treating method may include an operation of determining the flow amount according to the result of the comparison. In example embodiments, the controller of the substrate treatment apparatus may determine the flow amount according to the result of the comparison. In example embodiments, the substrate treating method may include an operation of determining a reference flow amount value to be the flow amount when the estimated vacuum pressure is less than or equal to the reference pressure as illustrated by “Yes” in operation S33. When the estimated vacuum pressure is less than or equal to the reference pressure, the substrate W may be predicted to be stably fixed to the chuck 110 by a vacuum pressure through the chuck 110. Here, the reference pressure may be a predetermined value. For example, the reference pressure may be a value set to one of values such as −35 KPa, −33 KPa, −31 KPa, or the like. The reference flow amount value may be a predetermined value. In this case, in operation S36, the chuck 110 may draw and secure the substrate W to the chuck 110 by the vacuum pressure which is generated according to a flow amount of the reference flow amount value. The vacuum pressure at a time of acquiring a vacuum pressure for a reference substrate may be generated according the flow amount of the reference flow amount value.

In example embodiments, the substrate treating method may include an operation of determining a value obtained by applying a weighted value corresponding to the estimated vacuum pressure to the reference flow amount value to be the flow amount when the estimated vacuum pressure is larger than the reference pressure as illustrated by “No” in operation S33. When the estimated vacuum pressure is larger than the reference pressure, the substrate W may be predicted not to be stably fixed to the chuck 110 by the vacuum pressure through the chuck 110. In example embodiments, the vacuum pressure may be decreased as the flow amount is increased. In this case, the value obtained by applying the weighted value may be larger than the reference flow amount value. In other words, the vacuum pressure may be formed to be lower than the estimated vacuum pressure by applying a flow amount having a value larger than the reference flow amount value. In this case, in operation S36, the chuck may suck the substrate W by the vacuum pressure which is generated according to a flow amount having the value obtained by applying the weighted value.

Hereinafter, the substrate treating method according to an example embodiment will be specifically described.

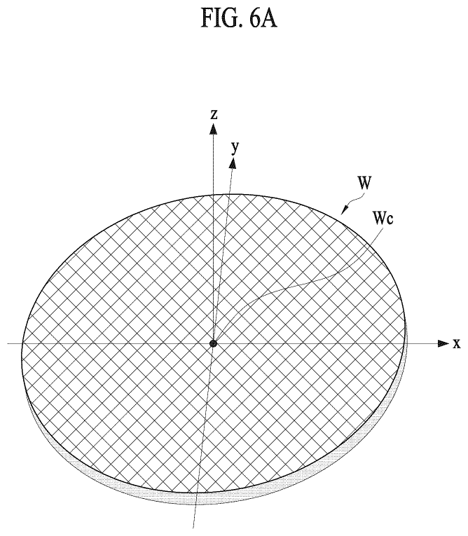

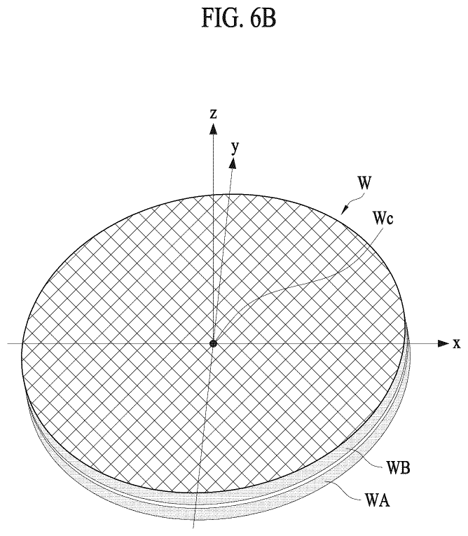

FIGS. 6A and 6B are diagrams for describing a substrate according to example embodiments.

Referring to FIGS. 6A and 6B, the substrate W according to example embodiments of the present disclosure may include at least one layer. For example, the substrate W may include at least one wafer. The above description of the substrate W may be identically applied to a reference substrate.

In example embodiments, the substrate W may have a single layer as illustrated in FIG. 6A. For example, the substrate W may include one wafer.

In another example embodiments, the substrate W may have a plurality of layers as illustrated in FIG. 6B. For example, the substrate W may include a plurality of wafers WA and WB. The plurality of wafers WA and WB may be stacked in a height-wise direction (e.g., a z-axis direction). Some areas between the plurality of wafers WA and WB may be bonded. The plurality of wafers WA and WB may be wafers of an identical type or wafers of different types.

In example embodiments, height values by position on the substrate W (or the reference substrate) may be measured, and a height value of the substrate W (or the reference substrate) may be determined based on the height values by position. Here, a height value may show a length in the height-wise direction (e.g., the z-axis direction). Here, a position may show a point in a horizontal direction perpendicular to the height-wise direction (e.g., the z-axis direction). The horizontal direction may include at least one horizontal direction. For example, the horizontal direction may include a first horizontal direction (e.g., an x-axis direction) and a second horizontal direction (e.g., a y-axis direction). The first horizontal direction (e.g., the x-axis direction) may be a direction perpendicular to the height-wise direction (e.g., the z-axis direction). The second horizontal direction (e.g., the y-axis direction) may be a direction different from the first horizontal direction (e.g., the x-axis direction) and a direction perpendicular to the height-wise direction (e.g., the z-axis direction). In example embodiments, an angle between the first horizontal direction and the second horizontal direction may be ninety degrees or another degree different therefrom (e.g., an angle smaller or larger than ninety degrees). The determined height value may be referred to as a representative height value.

In example embodiments, one substrate W (or one reference substrate) may have one height value (namely, the representative height value). For example, when a plurality of height values measured for one substrate W is present, one representative height value may be determined by using at least one of a largest height value, a smallest height value, an average height value, and a median height value of the plurality of height values.

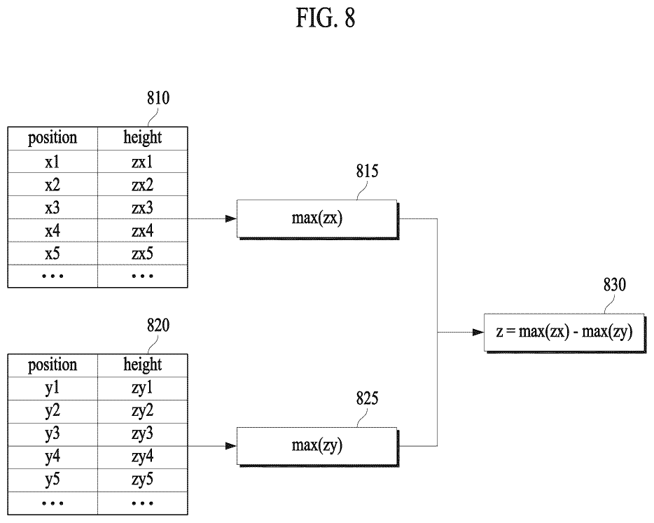

In example embodiments, the height value (namely, the representative height value) of the substrate W (or the reference substrate) may be determined by using height values by position in the first horizontal direction and height values by position in the second horizontal direction. Details thereof will be specifically described with reference to FIGS. 7 and 8.

In example embodiments, the height value (namely, the representative height value) of the substrate W (or the reference substrate) may be determined to be one of a largest height value, a smallest height value, an average height value, and a median height value of height values by position in a set area. For example, the set area may be an edge area. The edge area may be an area including positions having a distance larger than a set radius from a center We of the substrate W.

FIG. 7 is a diagram for describing height values by position according to example embodiments. FIG. 8 is a diagram for describing a scheme of determining a height value according to example embodiments.

Referring to FIGS. 7 and 8, height values by position in each direction of a first horizontal direction (e.g., an x-axis direction) and a second horizontal direction (e.g., a y-axis direction) may be measured for one substrate W according to example embodiments. A height value of the substrate W may be measured in a state in which the substrate W is loaded onto the chuck 110. However, it is merely an example embodiment, and the height value of the substrate W may be modified and implemented to be measured at another position. A description of the height value of the substrate W may be identically applied to a height value of a reference substrate.

In example embodiments, a height value at each position moved at a predetermined interval in the first horizontal direction (e.g., the x-axis direction) may be measured for one substrate W. For example, a first height value zx1 may be measured at a first position x1 in the first horizontal direction. A second height value zx2 may be measured at a second position x2 spaced apart from the first position x1 by a predetermined distance in the first horizontal direction. Such an operation may be repeated and implemented. As a result, height value data 710 and 810 for the first horizontal direction may be acquired. A height value at each position moved at a predetermined interval in the second horizontal direction (e.g., the y-axis direction) may be measured for the identical substrate W. For example, a first height value zy1 may be measured at a first position y1 in the second horizontal direction. A second height value zy2 may be measured at a second position y2 spaced apart from the first position y1 by a predetermined distance in the second horizontal direction. Such an operation may be repeated and implemented. As a result, height value data 720 and 820 for the second horizontal direction may be acquired.

Referring to FIG. 8, a height value 830 of the substrate W according to an example embodiment may be a value of a difference between a largest height value among height values by position in the first horizontal direction and a largest height value among height values among height values by position in the second horizontal direction.

Specifically, a largest value among a plurality of height values zx1 through zx5 and so on included in height value data 810 for the first horizontal direction may be determined to be a first largest height value 815 in the first horizontal direction. Here, the first largest height value 815 may be an absolute value having only a magnitude.

Also, a largest value among a plurality of height values zy1 through zy5 and so on included in height value data 820 for the second horizontal direction may be determined to be a second largest height value 825 in the second horizontal direction. Here, the second largest height value 825 may be an absolute value having only a magnitude.

In addition, a value of a difference between the first largest height value 815 and the second largest value 825 may be determined to be the height value 830 of the substrate W. The height value 830 of the substrate W may be referred to as a representative height value.

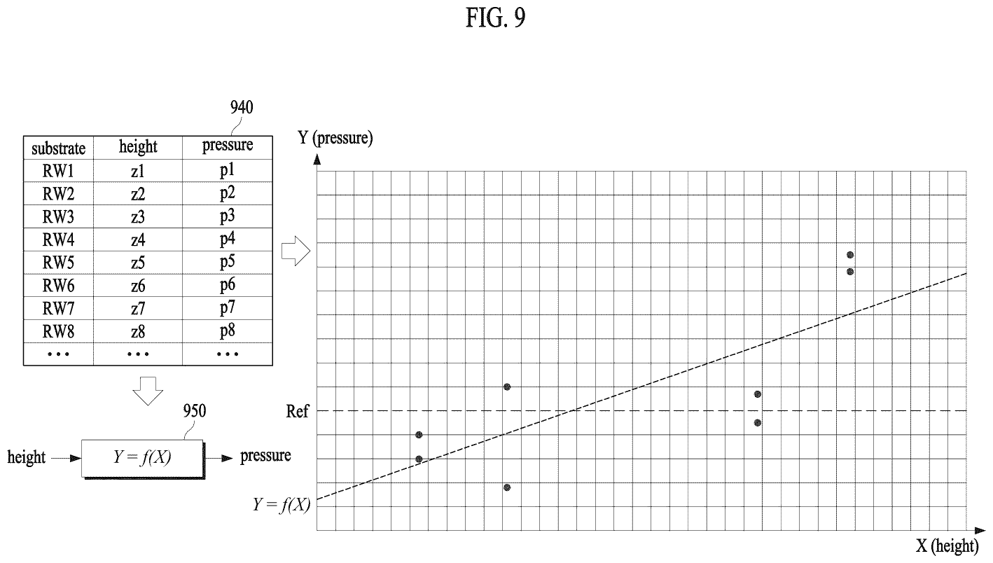

FIG. 9 is a diagram for describing correlation data according to example embodiments.

Referring to FIG. 9, a substrate treating method according to example embodiments may acquire a height value of and a vacuum pressure for each of a plurality of reference substrates RW1 through RW8 and so on. A description with reference to FIG. 8 or the like may be identically applied to the height value. A description with reference to FIG. 3 or the like may be identically applied to the vacuum pressure.

In example embodiments, the height value of and the vacuum pressure for each of the plurality of reference substrates RW1 through RW8 and so on may be stored as a data set 940 in a memory. For example, the data set 940 may be formed of a row and a column. In example embodiments, a height value of and a vacuum pressure that are acquired through an identical reference substrate may be stored in an identical row, and the height value and the vacuum pressure may be individually stored in different columns. For example, a height value of and a vacuum pressure for a first reference substrate RW1 may be stored in different columns in a first row, and a height value of and a vacuum pressure for a second reference substrate RW2 may be stored in different columns in a second row. A height value of and a vacuum pressure for another reference substrate may be stored in an identical manner.

In example embodiments, the height value of and the vacuum pressure for each of the plurality of reference substrates RW1 through RW8 and so on may be converted to a scatter plot. The scatter plot may be a graph showing relationship between two variables as a point on an XY-plane for which an X-axis and a Y-axis are set. The height value may be a value on the X-axis, and the vacuum pressure may be a value on the Y-axis.

In example embodiments, correlation data 950 may be acquired through the height value of and the vacuum pressure for each of the plurality of reference substrates RW1 through RW8 and so on. In example embodiments, the correlation data 950 may include a function having the height value as an input variable and the vacuum pressure (or an estimated vacuum pressure) as an output variable. Here, the function may be a function in various forms such as a linear function, a logarithmic function, or an exponential function.

In example embodiments, the correlation data 950 may include a linear function between the height value of each of the plurality of reference substrates and the vacuum pressure for each of the plurality of reference substrates. For example, the linear function may be defined as an equation such as “Y=A×X+B”. A may be a gradient, B may be a constant, X may be the height value, and Y may be the vacuum pressure or the estimated vacuum pressure.

In example embodiments, the linear function may be determined by using various algorithms such as a least squares method or RANSAC. For example, height values of and vacuum pressures for the plurality of reference substrates as shown by the following Table 1 may be acquired. In this case, the linear function which is acquired through the least squares method may be “Y=0.0674 X−41.379”.

TABLE 1

| Height value | Vacuum pressure |
|---|---|
| 62 | −36 |
| 62 | −37 |
| 81 | −34 |
| 81 | −38.2 |
| 135 | −35.5 |
| 135 | −34.3 |
| 155 | −29.2 |
| 155 | −28.5 |

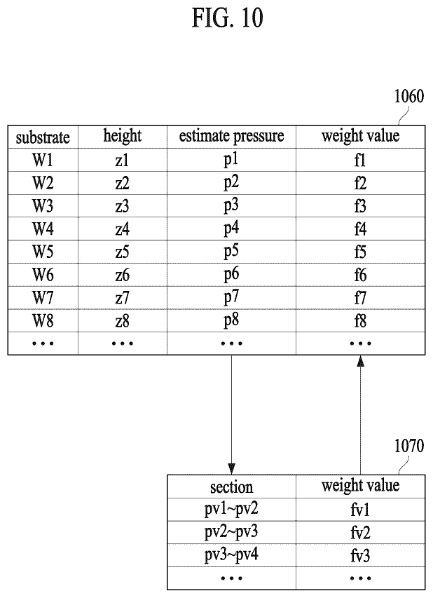

FIG. 10 is a diagram for describing an estimated vacuum pressure and a weighted value according to example embodiments.

Referring to FIGS. 9 and 10, a first table 1060 illustrates respective height values z1 through z8 and so on of, respective estimated vacuum pressures p1 through p8 and so on for, and respective weighted values f1 through f8 and so on for a plurality of substrates W1 through W8 and so on.

In example embodiments, the estimated vacuum pressures p1 through p8 and so on for the substrates W1 through W8 and so on may be acquired by using the correlation data 950. For example, when the height values z1 through z8 and so on of the substrates W1 through W8 and so on are input to the correlation data 950, the estimated vacuum pressures p1 through p8 and so on of the substrates W1 through W8 and so on may be acquired as an output value.

A first substrate W1 among the plurality of substrates W1 through W8 and so on will be described as an example. In example embodiments, when an estimated vacuum pressure p1 for the first substrate W1 is larger than a reference pressure Ref, the first substrate W1 may be expected to be abnormally fixed. When the estimated vacuum pressure p1 for the first substrate W1 is less than or equal to the reference pressure Ref, the first substrate W1 may be expected to be normally fixed. In this case, a flow amount is required to be increased for allowing the first substrate W1 to be normally fixed.

In example embodiments, the weighted values f1 through f8 and so on for the plurality of substrates W1 through W8 and so on may be determined. For example, a substrate to which a weighted value is to be applied may be determined according to a result of comparing the estimated vacuum pressures p1 through p8 and so on of the plurality of substrates W1 through W8 and so on with the reference pressure Ref. Values corresponding to the estimated vacuum pressures p1 through p8 and so on may be determined to be the weighted values f1 through f8 and so on. In example embodiments, the weighted values f1 through f8 and so on which correspond to the estimated vacuum pressures p1 through p8 and so on may be larger than values obtained by dividing the reference pressure Ref by the estimated vacuum pressures p1 through p8 and so on.

In example embodiments, a reference flow amount value may be determined to be a flow amount in a state in which a substrate having an estimated vacuum pressure less than or equal to the reference pressure Ref among the plurality of substrates W1 through W8 and so on is loaded onto the chuck 110.

In other example embodiments, a value obtained by applying a weighted value to the reference flow amount value may be determined to be the flow amount in the state in which the substrate having the estimated vacuum pressure less than or equal to the reference pressure Ref among the plurality of substrates W1 through W8 and so on is loaded onto the chuck 110. For example, a value obtained by multiplying the reference flow amount value by the weighted value may be the flow amount. In this case, the weighted value may be a value smaller than 1. In addition, the weighted value may be a value larger than a value obtained by dividing the reference pressure Ref by the estimated vacuum pressure.

For example, when the reference pressure Ref is −30 KPa, and when the estimated vacuum pressure is −35 KPa, the weighted value may have a value larger than 0.857 that is a value obtained by dividing the reference pressure by the estimated vacuum pressure. In other words, a value obtained by adding a positive constant to the value obtained by dividing the reference pressure by the estimated vacuum pressure (e.g., 0.9 or the like) may be determined to be the weighted value.

In example embodiments, the value obtained by applying the weighted value to the reference flow amount value may be determined to be the flow amount in a state in which a substrate having an estimated vacuum pressure larger than the reference pressure Ref among the plurality of substrates W1 through W8 and so on is loaded onto the chuck 110. For example, the value obtained by multiplying the reference flow amount value by the weighted value may be the flow amount. In this case, the weighted value may be a value larger than 1. In addition, the weighted value may be a value larger than a value obtained by dividing the reference pressure Ref by the estimated vacuum pressure.

For example, when the reference pressure Ref is −30 KPa, and when the estimated vacuum pressure is −25 KPa, the weighted value may be a value larger than 1.2 that is a value obtained by dividing the reference pressure by the estimated vacuum pressure. In other words, a value obtained by adding a positive constant to the value obtained by dividing the reference pressure by the estimated vacuum pressure (e.g., 1.3 or the like) may be determined to be the weighted value.

In example embodiments, a weighted value corresponding to an estimated vacuum pressure may be a weighted value mapped to a section including the estimated vacuum pressures p1 through p8 and so on among a plurality of weighted values fv1 through fv3 and so on individually mapped to a plurality of sections.

For example, a second table 1070 illustrates the plurality of weighted values fv1 through fv3 and so on individually mapped to the plurality of sections. The second table 1070 may be stored in a memory in advance. That is, the plurality of weighted values fv1 trough fv3 and so on individually mapped to the plurality of sections may be stored in the memory in advance. Each section may have a range not overlapping another. For example, a first section may have a range greater than or equal to a first value pv1 and less than a second value pv2. The second section may have a range greater than or equal to the second value pv2 and less than a third value pv3. Different sections each may have a unique range in such a manner.

For example, when the estimated vacuum pressure p1 for the first substrate W1 is included in the second section among the plurality of sections, a second weighted value fv2 mapped to the second section may be determined to be a weighted value f1 for the first substrate W1.

In other example embodiments, weighted values may be determined for all the plurality of substrates W1 through W8 and so on without magnitude comparison with the reference pressure Ref. For example, values obtained by adding a constant to the values obtained by dividing the reference pressure Ref by the estimated vacuum pressures p1 through p8 and so on may be determined to be the weighted values f1 through f8 and so on.

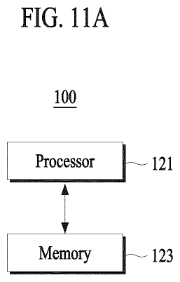

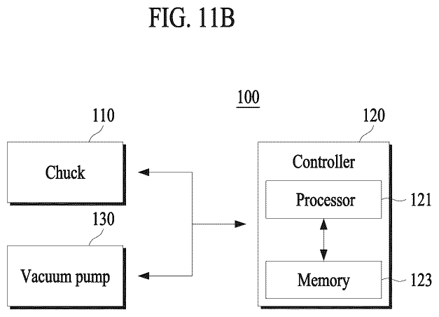

FIGS. 11A and 11B are block diagrams for describing a substrate treatment apparatus according to example embodiments.

Referring to FIGS. 11A and 11B, a substrate treatment apparatus 100 according to example embodiments of the present disclosure may be an apparatus that performs at least a portion of various unit processes for manufacturing an electric apparatus by treating the substrate W.

Referring to FIG. 11A, the substrate treatment apparatus 100 may include a processor 121 and a memory 123.

The processor 121 may perform various operations by executing a program stored in the memory 123. The processor 121 may be loaded with data stored in the memory 123 to calculate or process the data or may generate and send a control signal for controlling another element of the substrate treatment apparatus 100. For example, the processor 121 may be implemented as a central processing unit, a calculation circuit, a logic circuit, a microcontroller, a digital signal processor, or the like.

The processor 121 may determine a flow amount based on a height value of the substrate W and correlation data between a height value of and a vacuum pressure for each of a plurality of reference substrates.

In example embodiments, the processor 121 may acquire, as a height value of a reference substrate, a value of a difference between a largest height value among height values by position on the reference substrate in a first horizontal direction and a largest height value among height values by position on the reference substrate in a second horizontal direction. In example embodiments, the processor 121 may acquire, as the height value of the substrate W, a value of a difference between a largest height value among height values by position on the substrate W in the first horizontal direction and a largest height value among height values by position on the substrate W in the second horizontal direction.

In example embodiments, the processor 121 may acquire an estimated vacuum pressure corresponding to the correlation data and the height value of the substrate W. A controller 120 may compare the estimated vacuum pressure and the reference pressure Ref.

In example embodiments, the correlation data may include a linear function between the height value of each of the plurality of reference substrates and the vacuum pressure for each of the plurality of reference substrates. In example embodiments, the processor 121 may acquire the estimated vacuum pressure by inputting the value of the difference between the largest height value among the height values by position on the substrate W in the first horizontal direction and the largest height value among the height values by position on the substrate W in the second horizontal direction to the linear function.

In example embodiments, the processor 121 may determine a value obtained by applying a weighted value corresponding to the estimated vacuum pressure to a reference flow amount value to be the flow amount when the estimated vacuum pressure is larger than the reference pressure Ref. In this case, the weighted value may be a value larger than 1. Also, the weighted value may be a value larger than a value obtained by dividing the reference pressure Ref by the estimated vacuum pressure.

In example embodiments, the processor 121 may determine the reference flow amount value to be the flow amount when the estimated vacuum pressure is less than or equal to the reference pressure Ref.

In other example embodiments, the processor 121 may determine the value obtained by applying the weighted value corresponding to the estimated vacuum pressure to the reference flow amount value to be the flow amount when the estimate vacuum pressure is less than or equal to the reference pressure Ref. In this case, the weighted value may be a value smaller than 1. Also, the weighted value may be the value larger than the value obtained by dividing the reference pressure Ref by the estimated vacuum pressure.

The memory 123 may store a variety of data and the program executed by the processor 121. For example, the memory 123 may include at least one of various memories such as a dynamic random access memory (DRAM), a static random access memory (SRAM), a synchronous DRAM (SDRAM), or a NOT-AND (NAND) flash memory.

In example embodiments, the memory 123 may store the height value of each of the plurality of reference substrates. In example embodiments, the memory 123 may store the vacuum pressure for each of the plurality of reference substrates, which is measured in a state in which each of the plurality of reference substrates is loaded onto a chuck. In example embodiments, the memory 123 may store correlation data between the height value of and a vacuum pressure for the reference substrate. In example embodiments, the memory 123 may store at least one of a height value of and an estimated vacuum pressure for a substrate. In example embodiments, the memory 123 may store a plurality of weighted values. In example embodiments, the memory 123 may store the reference pressure Ref. In example embodiments, the memory 123 may store the reference flow amount value.

Referring to FIG. 11B, the substrate treatment apparatus 100 according to example embodiments may include the chuck 110, the controller 120, and the vacuum pump 130. The controller 120 may include the processor 121 and the memory 123.

The substrate W or the reference substrate may be loaded (or disposed) onto the chuck 110. The chuck 110 may drawn and secure the substrate W or the reference substrate to the chuck 110 by vacuum pressure. In example embodiments, the at least one hole 110h may be formed to the chuck 110.

The controller 120 may control overall operations of the substrate treatment apparatus 100 or perform processing of calculation of data. The controller 120 may include the processor 121 and the memory 123.

The vacuum pump 130 may generate the vacuum pressure according to the flow amount. Here, the flow amount may show an amount of a fluid discharged per unit time. The vacuum pump 130 may discharge an inner gas according to the flow amount, and the vacuum pressure may be generated according to the flow amount. The vacuum pressure generated by the vacuum pump 130 may be sent to the chuck 110 through a pipe. To this end, the vacuum pump 130 and the hole 110h of the chuck 110 may be connected through the pipe. That is, the vacuum pump 130 may discharge a gas in the hole 110h of the chuck 110 according to the flow amount. The vacuum pressure may be generated in the hole 110h of the hole 110. The vacuum pressure may be a pressure lower than an upper pressure (e.g., an atmospheric pressure) applied to an upper portion of the substrate W.

The vacuum pump 130 may operate according to control by the controller 120. For example, the vacuum pump 130 may generate the vacuum pressure according to the flow amount which is determined by the controller 120.

In example embodiments, the vacuum pump 130 may be one of various vacuum pumps such as a rotary vacuum pump that discharges the inner gas by rotation of a rotor and a vane, a wet vacuum pump that discharges the inner gas by evaporating oil or steam, a diffusion pump that discharges the inner gas by using diffusion of a gas molecule, a turbo molecular pump that discharges the inner gas by high-speed rotation of a turbine blade formed to a central axis of a motor, or an ion vacuum pump that discharges the inner gas by ionizing and collecting the inner gas.

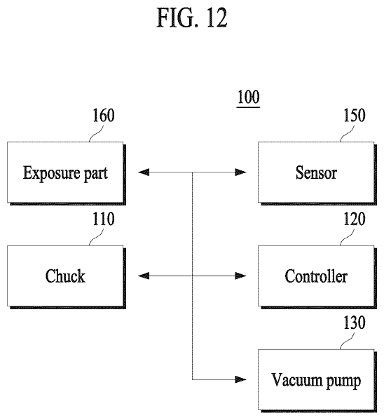

FIG. 12 is a block diagram for describing a substrate treatment apparatus according to example embodiments.

Referring to FIG. 12, the substrate treatment apparatus 100 according to example embodiments of the present disclosure may include the chuck 110, the controller 120, and the vacuum pump 130 and further include at least one of a sensor 150 and an exposure part 160. As being redundant and similar to the above description, a description of each of the chuck 110, the controller 120, and the vacuum pump 130 will be omitted.

In example embodiments, the sensor 150 may include a height sensor for measuring a height value of a reference substrate or the substrate W. The height sensor may acquire height values by position on the reference substrate or the substrate W. For example, the height sensor may be a sensor for measuring the height value with various method such as a triangulation scheme, a ToF scheme, a structure light scheme, or a contact scheme.

In example embodiments, the height sensor may acquire, as the height value of the reference substrate, a value of a difference between a largest height value among height values by position on the reference substrate in a first horizontal direction and a largest height value among height values by position on the reference substrate in a second horizontal direction. In example embodiments, the height sensor may acquire, as the height value of the substrate W, a value of a difference between a largest height value among height values by position on the substrate W in the first horizontal direction and a largest height value among height values by position on the substrate W in the second horizontal direction.

In example embodiments, the sensor 150 may include a pressure sensor for measuring a vacuum pressure for the reference substrate. The pressure sensor may measure the vacuum pressure for the reference substrate in a state in which the reference substrate is loaded onto the chuck 110. For example, the pressure sensor may be a sensor for measuring the vacuum pressure with various schemes, such as an ionization sensor, a thermocouple gauge, a diaphragm sensor, or an optical fiber pressure sensor.

The exposure part 160 may expose the substrate W to light while the substrate W is supported on the chuck 110. For example, the exposure part 160 may irradiate at least one area of the substrate W with the light in a state in which the substrate W is loaded onto the chuck 110. In other words, the substrate W may be exposed to the light in a state of being fixed to the chuck 110. The light may be ultraviolet or extreme ultraviolet. However, it is merely an example, and the light may be a variety of light.

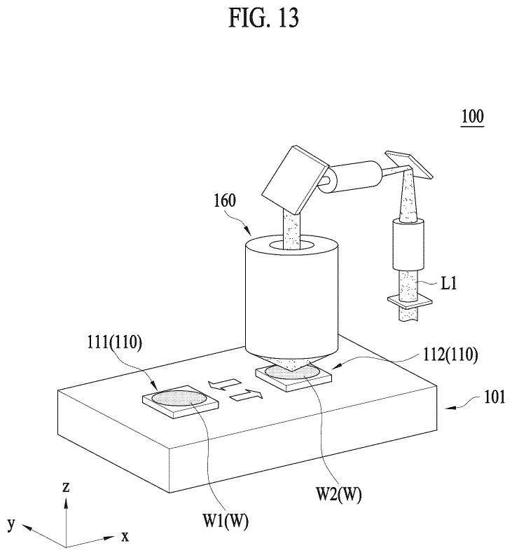

FIG. 13 is a diagram for describing a substrate treatment apparatus according to example embodiments.

Referring to FIG. 13, the substrate treatment apparatus 100 according to an example embodiment may include a stage 101, the chuck 110, and the exposure part 160. In example embodiments, the substrate treatment apparatus 100 may further include a controller (not illustrated) and a vacuum pump (not illustrated).

The stage 101 may support and fix the chuck 110. At least one chuck 110 may be disposed on the stage 101.

The substrate W may be disposed on the at least one chuck 110. In example embodiments, the chuck 110 may move in at least one direction among a first horizontal direction (e.g., an x-axis direction), a second horizontal direction (e.g., a y-axis direction), and a height-wise direction (e.g., a z-axis direction). In example embodiments, the chuck 110 may move in a rotating manner along a rotation axis.

In example embodiments, a plurality of chucks 110 may be present. For example, the chuck 110 may include a first chuck 111 and a second chuck 112. The first substrate W1 may be disposed on the first chuck 111, and a second substrate W2 may be disposed on the second chuck 112. In this case, a flow amount for suction of the first substrate W1 disposed on the first chuck 111 and a flow amount for suction of the second substrate W2 disposed on the second chuck 111 may be independently determined by using respective height values and respective pieces of correlation data thereof.

In example embodiments, the first chuck 111 and the second chuck 112 may be moved on the stage 101. Respective positions of the first chuck 111 and the second chuck 112 may be switched.

For example, the first chuck 111 may be positioned at a first position, and a height value may be measured for the first substrate W1 disposed on the first chuck 111. In this case, the second chuck 112 may be positioned at a second position, and exposure, to light, of the second substrate W2 disposed on the second chuck 112 may be performed through the exposure part 160. Afterward, the second substrate W2 may be discharged, and a third substrate may be disposed on the second chuck 112.

Then, the first chuck 111 may move to the second position, and the second chuck 112 may move to the first position. Exposure of the first substrate W1 to light may be performed through the exposure part 160, and a height value may be measured for the third substrate disposed on the second chuck 112. A unit process may be sequentially performed for a plurality of substrates in such a manner.

The exposure part 160 may include a light source, an optical system, a mask, and a mask stage.

The light source may generate and emit light L1. For example, the light L1 may be extreme ultraviolet having a wavelength greater than or equal to 5 nanometers (nm) and less than 50 nm or ultraviolet having a wavelength greater than or equal to 100 nm and less than 400 nm. However, it is merely an example, and the light L1 may be modified and implemented to be light having various wavelengths. The light L1 may be projected on the substrate W through the optical system and the mask.

The optical system may send the light L1 emitted from the light source to the mask. For example, the optical system may include a lens or a mirror for refracting the light L1 emitted from the light source or adjust a direction thereof. The optical system may include a filter that allows only a predetermined wavelength to penetrate.

The mask may allow the light to penetrate a predetermined area and may block the light for another area in order to form a circuit pattern. For example, the mask may include a substrate having a transparent material (e.g., sapphire, quartz, or the like) and a blocking film. In the blocking film, a material such as chrome that blocks or absorbs the light may be deposited to an area corresponding to the circuit pattern. The mask stage may arrange a position of the mask above an upper portion of the substrate W.

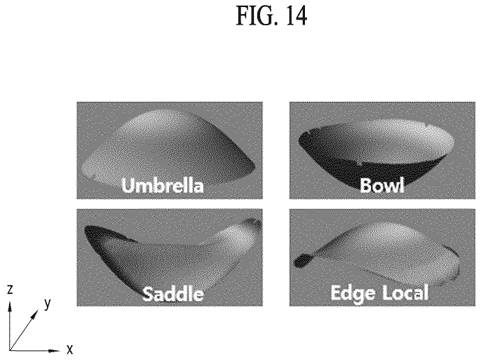

FIG. 14 is a diagram for describing a state of warpage of a substrate according to example embodiments.

Referring to FIG. 14, warpage may occur in the substrate W or a reference substrate according to example embodiments of the present disclosure due to various factors such as bonding or heat treatment.

As illustrated in FIG. 14, for example, a state of the warpage of the substrate W or the reference substrate may be a state such as an umbrella-like state, a bowl-like state, a saddle-like state, and an edge local-like state. Such states of the warpage may be an example embodiment, and the warpage may occur in a different form. A substrate treating method and the substrate treatment apparatus 100 may stably fix the substrate W which is in such a state of the warpage to the chuck 110. In the embodiments, the term “stably fix” may refer to applying vacuum to cause a warped or otherwise non-flat substrate to be positioned completely flat on the chuck, thereby adhering it securely. In the embodiments, the term “stably fix” may refer to preventing the movement of the substrate and continuously maintaining its fixed state.

For example, in a case of the umbrella-like state, a central area of the substrate W may have a shape convex in an upward direction. In this case, a height value of the central area, which is measured from a reference height, may be larger than a height value of an edge area, which is measured from the reference height.

For example, in a case of the bowl-like state, the central area of the substrate W may have a shape convex in a downward direction. In this case, the height value of the central area, which is measure from the reference height, may be smaller than the height value of the edge area, which is measured from the reference height.

For example, in cases of the saddle-like state and the edge local-like state, a height value of a substrate may vary in a first horizontal direction (e.g., an x-axis direction) and in a second horizontal direction (e.g., a y-axis direction).

In a case of the saddle-like state, a height value of the edge area in the first horizontal direction may be larger than the height value of the central area and a height value of the edge area in the second horizontal direction. The height value of the central area may be larger than the height value of the edge area in the second horizontal direction. In a case of the edge local-like state, the height value of the central area may be larger than the height value of the edge area in the first horizontal direction and the height value of the edge area in the second horizontal direction. The height value of the edge area in the second horizontal direction may be larger than the height value of the edge area in the first horizontal direction.

The substrate treatment apparatus 100 in accordance with the above-described embodiments may include a processor, a memory which stores and executes program data, a permanent storage such as a disk drive, a communication port for communication with an external device, and a user interface device such as a touch panel, a key, and a button. Methods realized by software modules or algorithms may be stored in a computer-readable recording medium as computer-readable codes or program commands which may be executed by the processor. Here, the computer-readable recording medium may be a magnetic storage medium (for example, a read-only memory (ROM), a random-access memory (RAM), a floppy disk, or a hard disk) or an optical reading medium (for example, a CD-ROM or a digital versatile disc (DVD)). The computer-readable recording medium may be dispersed to computer systems connected by a network so that computer-readable codes may be stored and executed in a dispersion manner. The medium may be read by a computer, may be stored in a memory, and may be executed by the processor.

The present embodiments may be represented by functional blocks and various processing steps. These functional blocks may be implemented by various numbers of hardware and/or software configurations that execute specific functions. For example, the present embodiments may adopt integrated circuit configurations such as a memory, a processor, a logic circuit, and a look-up table that may execute various functions by control of one or more microprocessors or other control devices. Similarly to that elements may be executed by software programming or software elements, the present embodiments may be implemented by programming or scripting languages such as C, C++, Java, and assembler language including various algorithms implemented by combinations of data structures, processes, routines, or of other programming configurations. Functional aspects may be implemented by algorithms executed by one or more processors. In addition, the present embodiments may adopt the related art for electronic environment setting, signal processing, and/or data processing, for example. The terms “mechanism”, “element”, “means”, and “configuration” may be widely used and are not limited to mechanical and physical components. These terms may include meaning of a series of routines of software in association with a processor, for example.

The above-described embodiments are merely examples and other embodiments may be implemented within the scope of the following claims.

What is claimed is:

1. A substrate treating method comprising:
identifying correlation data between a height value of each of a plurality of reference substrates and a vacuum pressure applied to secure each of the plurality of reference substrates to a chuck; and
determining, based on the correlation data and a height value of a substrate, a flow amount of a fluid discharged by a vacuum pump to produce a vacuum pressure applied to secure the substrate to the chuck.

2. The substrate treating method of claim 1, wherein the determining of the flow amount comprises:
acquiring an estimated vacuum pressure for the substrate, which corresponds to the height value of the substrate, through the correlation data; and
comparing the estimated vacuum pressure to a reference vacuum pressure.

3. The substrate treating method of claim 2, wherein the determining of the flow amount further comprises determining a reference flow amount value to be the flow amount when the estimated vacuum pressure is less than or equal to the reference vacuum pressure.

4. The substrate treating method of claim 2, wherein the determining of the flow amount further comprises determining a value obtained by applying a weighted value corresponding to the estimated vacuum pressure to a reference flow amount value to be the flow amount when the estimated vacuum pressure is larger than the reference vacuum pressure.

5. The substrate treating method of claim 4, wherein the weighted value corresponding to the estimated vacuum pressure is a weighted value mapped to a section including the estimated vacuum pressure among a plurality of weighted values individually mapped to a plurality of sections.

6. The substrate treating method of claim 4, wherein the weighted value corresponding to the estimated vacuum pressure is larger than a value obtained by dividing the reference vacuum pressure by the estimated vacuum pressure.

7. The substrate treating method of claim 1, further comprising:
acquiring the height value of each of the plurality of reference substrates;
acquiring the vacuum pressure applied to secure each of the plurality of reference substrates to the chuck; and
acquiring the correlation data between the height value of each of the plurality of reference substrates and the vacuum pressure applied to secure each of the plurality of reference substrates to the chuck.

8. The substrate treating method of claim 1, wherein the correlation data includes a linear function between the height value of each of the plurality of reference substrates and the vacuum pressure applied to secure each of the plurality of reference substrates to the chuck.

9. The substrate treating method of claim 1, wherein the height value of each of the plurality of reference substrates is a height value at a specific position on each of the plurality of reference substrates.

10. The substrate treating method of claim 9, wherein the height value of each of the plurality of reference substrates is a difference between a largest height value on each of the reference substrates along a first direction and a largest height value on each of the reference substrates along a second direction that is different from the first direction.

11. The substrate treating method of claim 10, wherein the height value of the substrate is a difference between a largest height value on the substrate along the first direction and a largest height value on the substrate along the second direction.

12. The substrate treating method of claim 1, further comprising selecting the plurality of reference substrates from a plurality of substrates for which an identical unit process is to be performed.

13. A substrate treatment apparatus comprising:
a memory configured to store correlation data between a height value of each of a plurality of reference substrates and a vacuum pressure applied to secure each of the plurality of reference substrates to a chuck; and
a processor configured to identify the correlation data and determine, based on the correlation data and a height value of a substrate, a flow amount of a fluid discharged by a vacuum pump to produce a vacuum pressure applied to secure the substrate to the chuck.

14. The substrate treatment apparatus of claim 13, wherein the processor is further configured to:
acquire an estimated vacuum pressure for the substrate, which corresponds to the height value of the substrate, through the correlation data; and
determine the flow amount by comparing the estimated vacuum pressure to a reference vacuum pressure.

15. The substrate treatment apparatus of claim 14, wherein the processor is further configured to determine a value obtained by applying a weighted value corresponding to the estimated vacuum pressure to a reference flow amount value to be the flow amount when the estimated vacuum pressure is larger than the reference vacuum pressure.

16. The substrate treatment apparatus of claim 14, wherein the processor is further configured to determine a reference flow amount value to be the flow amount when the estimated vacuum pressure is less than or equal to the reference vacuum pressure.

17. The substrate treatment apparatus of claim 14, wherein the correlation data comprises a linear function between the height value of each of the plurality of reference substrates and the vacuum pressure applied to secure each of the plurality of reference substrates to the chuck.

18. The substrate treatment apparatus of claim 17, wherein the processor is further configured to acquire the estimated vacuum pressure by inputting a value of a difference between a largest height value on the substrate along a first direction and a largest height value on the substrate along a second direction that is different from the first direction, as the height value of the substrate, to the linear function.

19. The substrate treatment apparatus of claim 13, further comprising:
the vacuum pump configured to generate the vacuum pressure according to the flow amount; and
the chuck to which the substrate is secured by the vacuum pressure.

20. A substrate treatment apparatus comprising:
a height sensor configured to measure a height value of a substrate;
a vacuum pump;
a chuck configured to support the substrate;
a controller in communication with the height sensor and the vacuum pump, wherein the controller is configured to:
acquire an estimated vacuum pressure for the substrate corresponding to the height value of the substrate based on correlation data between height values of a plurality of reference substrates and vacuum pressures applied to secure the plurality of reference substrates to the chuck; and
determine a flow amount of a fluid discharged by the vacuum pump, based on the estimated vacuum pressure; and
an exposure part configured to expose the substrate to light when the substrate is secured to the chuck.
